(19) United States
(12) Patent Application Publication
(10) Pub. No.: US 2017/0025509 A1
(43) Pub. Date: Jan. 26, 2017

(54) STRAINED SILICON GERMANIUM FIN WITH CONTROLLED JUNCTION FOR FINFET DEVICES

(71) Applicant: International Business Machines Corporation, Armonk, NY (US)

(72) Inventors: Kangguo Cheng, Schenectady, NY (US); Shogo Mochizuki, Clifton Park, NY (US); Alexander Reznicek, Troy, NY (US); Chun Wing Yeung, Niskayuna, NY (US)

(21) Appl. No.: 14/808,441

(22) Filed: Jul. 24, 2015

(51) Int. Cl. H01L 29/417; H01L 21/324; H01L 21/306; H01L 21/225; H01L 29/66; H01L 29/78

(52) U.S. Cl. CPC H01L 29/41791; H01L 29/66553; H01L 29/66795; H01L 29/785; H01L 21/30604; H01L 21/2253; H01L 21/324

(57) ABSTRACT

FinFET structures are formed on silicon germanium fins. Both the sides and the top surfaces of the source/drain regions of the fins are etched, thereby exposing portions of the channel regions of the fins within gate spacers. Doped source/drain structures are epitaxially grown on the source/drain regions of the fins and exposed channel regions to obtain a uniform junction profile through the fin height direction as well as the fin top surface.

### FIELD

The present disclosure relates to the physical sciences, and, more particularly, to non-planar structures employed in FinFET devices and methods of fabrication thereof.

### BACKGROUND

Fin-type field-effect transistors (FinFETs) have three-dimensional, non-planar configurations including fin-like structures extending above substrates. The substrates may include semiconductor on insulator (SOI) substrates or bulk semiconductor substrates. Silicon fins are formed in some FinFETs on substrates via known technology such as sidewall image transfer (SIT). FinFET structures including SOI substrates can be formed, in part, by selectively etching the crystalline silicon layers down to the oxide or other insulating layers thereof following photolithography. Active fin heights are set by SOI thickness when employing SOI substrates. In bulk FinFETs, active fin height is set by oxide thickness and etched fin height. The gates of FinFETs can be formed using a “gate-first” process wherein a gate stack and spacers are formed prior to selective epitaxial growth wherein source and drain regions are enlarged. A “gate-last” process may alternatively be employed wherein the source/drain regions are formed immediately following fin patterning. Gate-last procedures can involve making a dummy gate, fabricating other elements of the transistor, removing the dummy gate, and replacing the removed dummy gate with actual gate materials.

FinFET devices including silicon germanium fins enable improvements in performance with respect to silicon-based devices. Channel materials including high germanium content offer potential for developing 7 nm and later nodes.

Embedded source/drain epitaxial structures with recesses in the source/drain regions of the fins is useful for channel strain enhancement and junction engineering for silicon FinFET devices. However, recessing source/drain fin regions of strained silicon germanium FinFET devices raises concerns about relaxation of the compressive strain in the channel regions of the fins. The compressive strain might not be recovered by embedded source/drain epitaxial film.

### SUMMARY

Principles of the present disclosure provide an exemplary fabrication method that includes obtaining a structure comprising a substrate, a plurality of rows of parallel silicon germanium fins on the substrate, and a plurality of parallel gate structures on the substrate. The gate structures extend across the rows of parallel silicon germanium fins. The structure further includes a plurality of spacers on the parallel gate structures. The fins have channel regions extending through the gate structures and source/drain regions outside the spacers. The fabrication method further includes removing portions of the source/drain regions of the parallel silicon germanium fins, thereby reducing the widths and heights of the source/drain regions of the parallel silicon germanium fins and exposing portions of the channel regions. Doped source/drain epitaxial structures are epitaxially grown on the source/drain regions of the parallel silicon germanium fins and the exposed portions of the channel regions.

A FinFET structure provided in accordance with the principles discussed herein includes a substrate and a plurality of rows of parallel silicon germanium fins on the substrate, each of the fins including a channel region and source/drain regions. A plurality of parallel gate structures on the substrate extend across the channel regions of the fins. A plurality of spacers are on the parallel gate structures. A dielectric layer is on the substrate and between the parallel silicon germanium fins. The FinFET structure further includes doped source/drain epitaxial structures on the source/drain regions of the parallel silicon germanium fins and doped source/drain extension regions between the channel regions and the source/drain regions of the fins. The doped source/drain extension regions and the doped source/drain epitaxial structures contain the same dopant. The source/drain regions of the parallel silicon germanium fins have smaller height and width dimensions than the channel regions thereof. The channel regions include exposed surfaces within the spacers and the doped source/drain epitaxial structures extend within the spacers and directly contact the exposed surfaces of the channel regions.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Finned structures, including devices made from such finned structures, and fabrication methods as disclosed herein can provide substantial beneficial technical effects. For example, one or more embodiments may provide one or more of the following advantages:
High channel mobility and current drive;
Minimal channel strain relaxation;
Uniform junction profile;
Integratable with FinFET CMOS process flow.

These and other features and advantages will become apparent from the following detailed description of illustrative embodiments thereof, which is to be read in connection with the accompanying drawings.

### BRIEF DESCRIPTION OF THE DRAWINGS

FIG. 1A is a top view of a structure including a silicon substrate, silicon germanium fins, and gate structure;

FIG. 1B is a schematic sectional illustration of the structure shown in FIG. 1A including further gate structures;

FIG. 1C is a schematic perspective view of a portion of the structure shown in FIG. 1B;

FIG. 2 is a schematic perspective view of the structure shown in FIG. 1C following etching of the fins, and

FIG. 3 is a schematic perspective view showing the structure of FIG. 2 following growth of epitaxial source/drain structures.

### DETAILED DESCRIPTION

FinFET structures are characterized by fins formed on semiconductor substrates. Such substrates include bulk silicon substrates (fin on bulk) and SOI substrates (fin on SOI) as discussed above. The exemplary processes discussed below are described with respect to fabrication of FinFET devices from bulk silicon substrates having silicon germanium fins. The disclosed techniques can also be applied with respect to SOI or SGOI (silicon germanium on insulator) substrates. Exemplary steps that may be performed sequentially in fabricating FinFET devices are schematically illustrated in the figures. Fabrication may commence with a partially completed structure, in which case one or more of the steps described below could be omitted.

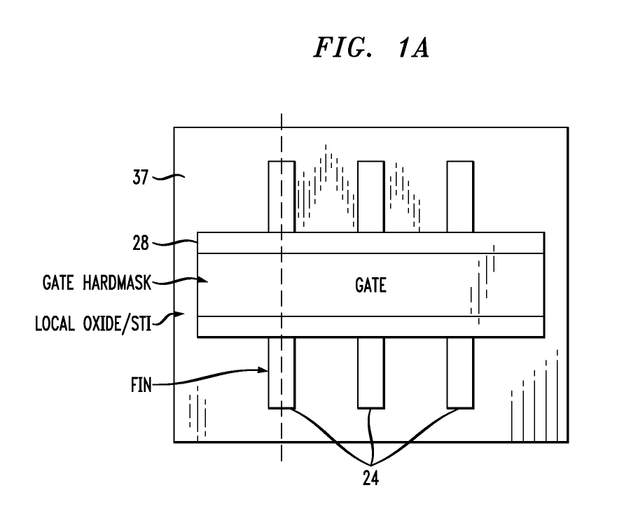

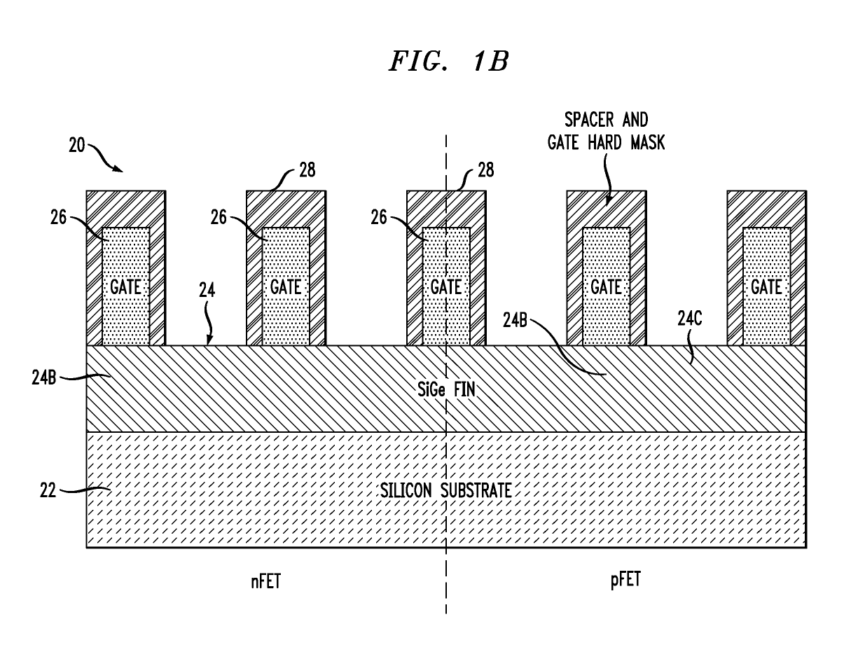

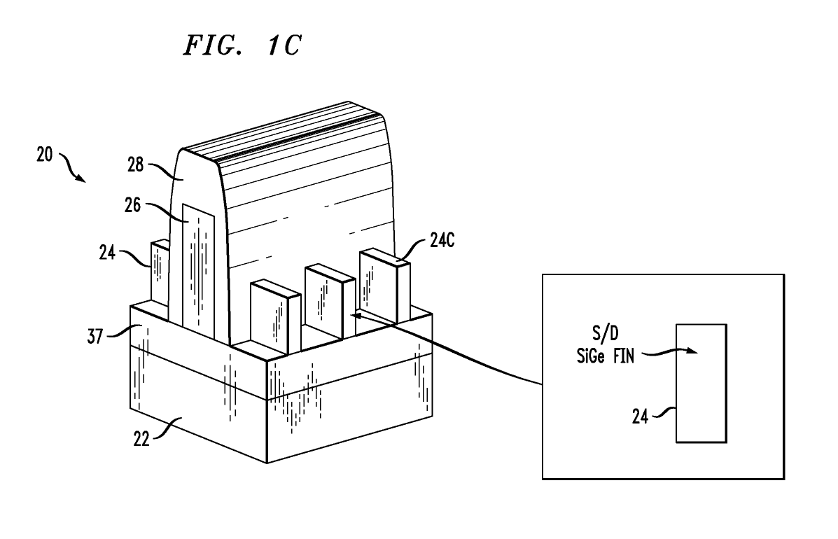

A structure 20 including a monocrystalline silicon substrate 22 consisting of essentially undoped monocrystalline silicon and silicon germanium fins 24 on the substrate is shown schematically in FIGS. 1A-1C, it being appreciated that standard silicon substrates may have a very low level of p-doping. The substrate may be in the form of a wafer. In some embodiments, the fins have a germanium content between twenty and fifty percent (20-50%). The fins 24 are Si₁₋ₓGeₓ where x is 0.2 or greater in some embodiments. Fin pitch is 25-50 nm and fin heights are 25-60 nm in one or more embodiments. A smaller pitch of 30-45 nm is employed in other embodiments. Fin width is six to ten nanometers (6-10 nm) in exemplary embodiments. Gate structures 26 are formed on the substrate 22. In some embodiments, the gate structures are dummy gates designed for later replacement. Alternatively, gate stacks including gate metal and gate dielectric layers are formed on the substrate 22. Any gate pitch suitable for the intended application of the completed product may be chosen. If a gate-first process as described above is employed, gate materials may comprise a gate dielectric (e.g., high-k such as hafnium oxide) and a gate conductor (e.g., metal gate). Any suitable deposition techniques can be used to deposit high-k and metal gate. For example, gate dielectric can be deposited using techniques including but not limited to atomic layer deposition (ALD), chemical vapor deposition (CVD), physical vapor deposition (PVD), molecular beam deposition (MBD) or pulsed laser deposition (PLD). Metal deposition techniques for depositing gate electrode materials include but are not limited to CVD, PVD, ALD, sputtering and plating. Spacers 28 are formed on the gate structures 26 and function as a hard mask. A silicon nitride (Si₃N₄) layer is deposited via CVD, PECVD, sputtering, or other suitable technique in some embodiments, forming the spacers 28. The spacers can include a single layer or be multi-layer. Spacer thickness is between two and ten nanometers (2-10 nm) in some embodiments. Spacers can be formed by any method known in the art, including depositing a conformal nitride layer over the gate structures and removing unwanted material using an anisotropic etching process such as reactive ion etching or plasma etching. The gate structures 26 and associated spacers 28 protect the underlying portions of the SiGe fins 24 that later function as channel regions of FinFET devices. Fin regions outside the gate structures and spacers later function as source/drain regions. Source/drain extensions are formed between the channel and source/drain regions of the fins, as described further below. As shown in FIGS. 1A and 1C, a dielectric layer 37 adjoins the substrate 22. Materials such as silicon dioxide can be used to form the dielectric layer 37.

While the fins 24 are shown as having vertical side walls and horizontal top surfaces in the schematic illustrations, it will be appreciated that fins in FinFET structures may have somewhat different configurations such as triangular configurations wherein the fin bases are wider than the tops of the fins. For example, tapered fins formed on bulk silicon substrates facilitate filling the cavities between fins with oxide materials without forming voids. The structure 20 may accordingly include fins 24 having sides that are not completely vertical. Fin heights are preferably equal. Fin heights, widths and spacing are further chosen in accordance with manufacturer preferences. Fin heights in some embodiments range between 25-60 nm. The side walls of the silicon germanium fins 22 are (110) surfaces. As discussed above, the side walls of the fins 22 may not be exactly vertical. Surfaces described as (110) surfaces herein are at least close to being (110) surfaces but may or may not be exactly (110) surfaces.

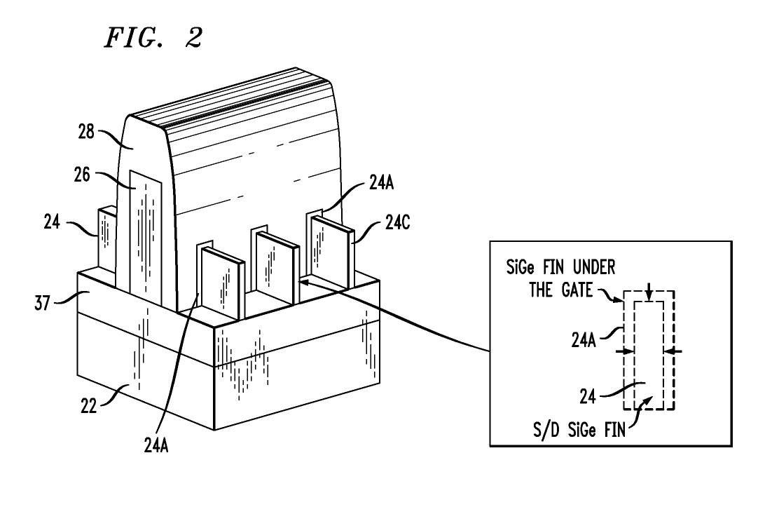

Referring to FIG. 2, the silicon germanium fins 24 are selectively etched to remove material from both the sidewalls and top surfaces in the source/drain regions while leaving the dielectric layer and spacer substantially intact. The etch is discontinued once the desired fin dimensions in the source/drain regions have been obtained. The following process can be conducted in-situ, prior to the source/drain epitaxial growth, without leaving the epitaxial reactor in some embodiments. The fins 24 are exposed in an epitaxial reactor to gaseous HCl, etching the fins 24 two to three nanometers (2-3 nm), as well as etching part of the fins under the spacers 28. Temperature is maintained between 600-650° C., HCl gas flow is 100-200 sccm, and carrier gas flow (hydrogen) is ten to twenty standard liters per minute (10-20 slm). Alternative, but less preferred etch processes for reducing the dimensions of the fins 24 and etching under the spacers 28 include wet etch or anisotropic RIE etch processes. In an exemplary embodiment where the original fins 24 have widths of eight nanometers, two nanometers are removed from each sidewall of the fins as well as the top surface of the source/drain regions thereof. The dimensions of the channel regions of the fins, being protected by the gate structure and spacers 28, remain unchanged. The same amount of material (in nanometers) is removed from the top surface and sidewalls of the source/drain region of each fin in one or more embodiments. By removing material from both the sidewalls and top surface of the fins, channel strain relaxation is minimized. The removal of fin material from the source/drain regions of the fins exposes portions 24A of the channel regions of the fins 24 that are within the spacers 28. A small amount of fin material within the spacers 28 is also removed during the etch such that the exposed surfaces of the channel regions are recessed within the spacers. In some embodiments, for example, two nanometers of fin material is removed from beneath the spacer. The surfaces of the exposed channel regions 24A are substantially perpendicular to the sidewall surfaces and top surfaces of the etched source/drain regions of the silicon germanium fins 24. The original dimensions of the fin portions protected by the gate structures 26 and spacers 28 remain unchanged throughout most of the protected area. Etching is discontinued prior to forming a recess that extends beyond the thickness of the spacers 28. For example, in cases where a typical spacer has a thickness of six nanometers, etching is discontinued about two or three nanometers under the spacer, leaving about three or four nanometers of the fin intact under the spacer. The maximum etch in some embodiments is half the spacer thickness.

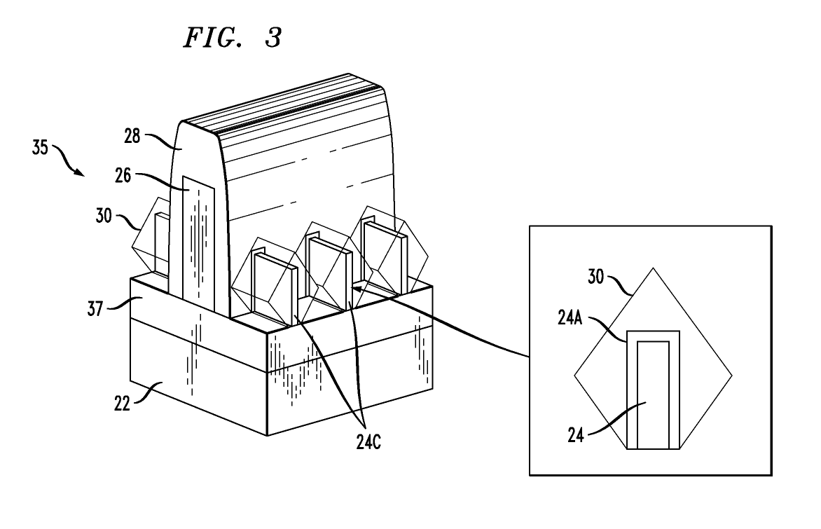

Referring to FIG. 3, expanded source/drain structures 30 are grown epitaxially on the exposed source/drain portions of the fins 24. Either p-type devices or n-type devices can be fabricated depending on the conductivity types of the epitaxial source/drain structures 30. In embodiments where n-type FinFET devices are to be formed, in-situ n-doped silicon may be used to form the epitaxial source/drain structures. An n-type dopant such as phosphorus or arsenic is employed in one or more embodiments. In-situ doping of the source/drain structures 30 can be conducted using conventional precursor materials and techniques. Source/drain epitaxy to form p-doped source/drain regions may include the introduction of boron precursor gas such as diborane. The p-doped source/drain structures consist essentially of boron-doped silicon germanium in one or more exemplary embodiments. In some embodiments, the epitaxial source/drain structures consist essentially of p-doped silicon germanium having the composition Si_{1-z}Ge_{z} where z is 0.3 or greater. Exemplary epitaxial growth processes that are suitable for use in forming the silicon and silicon germanium epitaxy include rapid thermal chemical vapor deposition (RTCVD), low-energy plasma deposition (LEPD), ultra-high vacuum chemical vapor deposition (UHVCVD), atmospheric pressure chemical vapor deposition (APCVD) and molecular beam epitaxy (MBE). The temperature for epitaxial deposition processes typically ranges from 550° C. to 900° C. Although higher temperature typically results in faster deposition, the faster deposition may result in crystal defects and film cracking Germanium and silicon precursors (e.g. germane and silane) are introduced in the proper ratios to obtain the targeted germanium content of silicon germanium source/drain structures 30. The doped, epitaxial source/drain structures 30, whether p-type or n-type, extend above the top surfaces of the source/drain regions of the fins 24, as shown in FIG. 3. Epitaxial deposition of the in-situ doped source/drain material is selective to the exposed areas of the silicon germanium fins 24, including the exposed channel region 24A just within the spacers 28. The source/drain material does not grow in the regions between fins, which include a local oxide layer 37 as shown in FIGS. 1A and 1C, or on the spacers 28. The ratio of silicon and germanium precursors (e.g. silane and germane) is maintained constant during epitaxial deposition to provide a substantially uniform ratio of silicon to germanium within silicon germanium source/drain structures that may be formed on the channel regions of the fins. The resulting structure 35 accordingly includes source/drain structures that are phosphorus or arsenic doped to obtain nFET devices and boron-doped to obtain pFET devices. Dopants contained within the epitaxial source/drain structures 30 are driven into the source/drain regions of the fins upon annealing the structure. The dopants also diffuse within the fin region under the spacers due to the direct contact made between the doped epitaxial source/drain structures 30 and the exposed surfaces 24A of the channel regions. The dopants diffuse partially into the channel regions of the silicon germanium fins during the annealing process, thereby forming doped source/drain extensions. Techniques such as rapid thermal anneal (RTA) may be employed to cause dopant diffusion and formation of source/drain extensions. A more uniform junction between the channel regions and source/drain regions is accordingly obtained without material relaxation of compressive strain in the channel regions of the silicon germanium fin. The techniques disclosed herein also facilitate junction engineering of strained SiGe FinFET devices.

The diamond-shaped source/drain structures 30 of uniformly doped semiconductor material are formed on the exposed sidewalls of the fins 24 by epitaxial growth. Faceted structures are formed on the fins as the silicon germanium (or silicon) epitaxy forms on (110) planes, thereby enlarging the source/drain regions of the fins 24. Fin sidewall surfaces are (110) surfaces in one or more embodiments, epitaxial growth thereon resulting in diamond-shaped structures due to the fact that the growth rate on (111) planes is considerably less than on (110) planes (100 is fastest), therefore self-limiting diamond-shaped structures are formed. Growth is limited in this exemplary embodiment to avoid merging of the faceted structures. Those of skill in the art are familiar with processes for growing such structures. The choice of semiconductor materials and dopants depends on the type of device to be fabricated and desired device characteristics. Doping levels high enough to provide the desired electrical properties can be beneficial in reducing defects. In one exemplary embodiment where the doped source/drain semiconductor material is SiGe containing about thirty-five percent (35%) germanium, the dopant is boron in a concentration ranging 6-9×10²⁰ cm⁻³ and the resulting FinFET structure is p-type. As discussed above, the resulting structure 40 may be subjected to rapid thermal anneal following formation of the unmerged diamond-shaped structures to drive dopant into the fins 24, including under the spacer 28, to form the extensions/junctions having uniform junction profiles.

Given the discussion thus far and with reference to the exemplary embodiments discussed above and the drawings, it will be appreciated that, in general terms, an exemplary fabrication method includes obtaining a structure including a substrate 22, a plurality of rows of parallel silicon germanium fins 24 on the substrate, a plurality of parallel gate structures 26 on the substrate and extending across the rows of parallel silicon germanium fins, and a plurality of spacers 28 on the parallel gate structures. The parallel silicon germanium fins have channel regions 24B extending through the gate structures 26 and source/drain regions 24C outside the spacers 28, as shown in FIG. 1B. Portions of the source/drain regions 24C of the parallel silicon germanium fins 24 are removed, thereby reducing the widths and heights of the source/drain regions 24C of the parallel silicon germanium fins and exposing portions 24A of the channel regions 24B. FIG. 2 shows an exemplary structure following removal of material from the sides and tops of the fins 24 in the source/drain regions thereof. Doped source/drain epitaxial structures 30 are epitaxially grown on the source/drain regions 24C of the parallel silicon germanium fins 22 and the exposed portions 24A of the channel regions 24B. Such growth is schematically illustrated in FIG. 3. The removal of portions of the source/drain regions 24C further includes subjecting the structure to a selective etch process such that the exposed portions 24A of the channel regions 24B are formed inside the spacers. In one or more embodiments, the source/drain regions 24C have sidewalls including (110) surfaces and the doped source/drain epitaxial structures are grown as faceted, diamond-shaped structures on the (110) surfaces. The method may further include annealing the structure and the doped source/drain epitaxial structures, thereby driving dopants from the doped source/drain epitaxial structures 30 into the source/drain regions 24C and partially into the channel regions 24B.

An exemplary FinFET structure includes a substrate 22 and a plurality of rows of parallel silicon germanium fins 24 on the substrate. Each of the fins includes a channel region 24B and source/drain regions 24C. Gate structures 26 extend across the channel regions 24B of the silicon germanium fins. Spacers are on the parallel gate structures. A dielectric layer 37 on the substrate extends between the silicon germanium fins 22. Doped source/drain epitaxial structures 30 are on the source/drain regions 24C of the silicon germanium fins 24. Doped source/drain extension/junction regions extend between the channel regions 24B and the source/drain regions 24C of the parallel silicon germanium fins. The source/drain extension regions and the doped source/drain epitaxial structures 30 contain the same dopant and accordingly have the same conductivity type. The source/drain regions 24C have smaller height and width dimensions than the channel regions 24B thereof. Due to the difference in dimensions, the channel regions include exposed surfaces 24A within the spacers 28. The doped source/drain epitaxial structures 30 extend within the spacers 28 and directly contact the exposed surfaces 24A of the channel regions. FIG. 3, considered in conjunction with the other figures, schematically illustrates an exemplary FinFET structure 35. The exposed surfaces 24A of the channel regions 24B of the parallel silicon germanium fins include first and second vertical surfaces adjoining and extending substantially perpendicularly to the sidewalls of the source/drain regions 24C and top, horizontal surfaces extending between the first and second parallel surfaces. The top, horizontally extending surface portions of the exposed surfaces 24A are substantially perpendicular with respect to the top surfaces of the source/drain regions 24C of the fins 24, as shown in FIG. 2. In some embodiments, the spacers 28 have thicknesses between two and ten nanometers and the source/drain epitaxial structures extend between two and five nanometers within the spacers. The parallel silicon germanium fins 24 consist essentially of Si₁₋ₓGeₓ where x is 0.2 or greater in some embodiments.

Those skilled in the art will appreciate that the exemplary structures discussed above can be distributed in raw form or incorporated as parts of intermediate products or end products such as integrated circuits that benefit from having non-planar electronic devices such as FinFETs therein.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “above” and “below” are used to indicate relative positioning of elements or structures to each other as opposed to relative elevation. It should also be noted that, in some alternative implementations, the steps of the exemplary methods may occur out of the order noted in the figures. For example, two steps shown in succession may, in fact, be executed substantially concurrently, or certain steps may sometimes be executed in the reverse order, depending upon the functionality involved.

The corresponding structures, materials, acts, and equivalents of all means or step plus function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

What is claimed is:

1. A method comprising:
obtaining a structure comprising a substrate, a plurality of rows of parallel silicon germanium fins on the substrate, a plurality of parallel gate structures on the substrate and extending across the rows of parallel silicon germanium fins, and a plurality of spacers on the parallel gate structures, the parallel silicon germanium fins having channel regions extending through the gate structures and source/drain regions outside the spacers;
removing portions of the source/drain regions of the parallel silicon germanium fins, thereby reducing the widths and heights of the source/drain regions of the parallel silicon germanium fins and exposing portions of the channel regions, and
epitaxially growing doped source/drain epitaxial structures on the source/drain regions of the parallel silicon germanium fins and the exposed portions of the channel regions.

2. The method of claim 1, wherein the step of removing portions of the source/drain regions further includes subjecting the structure to a selective etch process such that the exposed portions of the channel regions are formed inside the spacers.

3. The method of claim 2, wherein the structure further includes a dielectric layer on the substrate and between the parallel silicon germanium fins.

4. The method of claim 3, wherein the source/drain regions have sidewalls including (110) surfaces, and wherein the step of epitaxially growing the doped source/drain epitaxial structures further includes growing the doped source/drain epitaxial structures as faceted structures on the (110) surfaces.

5. The method of claim 4, further including the step of annealing the structure and the doped source/drain epitaxial structures, thereby driving dopants from the doped source/drain epitaxial structures into the source/drain regions and partially into the channel regions.

6. The method of claim 5, wherein the parallel silicon germanium fins of the structure have widths between six and ten nanometers, and further wherein the selective etch process causes reduction of the widths of the source/drain regions of the parallel silicon germanium fins by two nanometers or more.

7. The method of claim 6, wherein the selective etch process further causes reduction of the heights of the source/drain regions of the parallel silicon germanium fins by two nanometers or more.

8. The method of claim 1, further including the step of annealing the structure and the doped source/drain epitaxial structures, thereby driving dopants from the doped source/drain epitaxial structures into the source/drain regions and the channel regions of the parallel silicon germanium fins.

9. The method of claim 8, wherein:
the structure further includes a dielectric layer on the substrate and between the parallel silicon germanium fins, and
the step of removing portions of the source/drain regions of the parallel silicon germanium fins further includes subjecting the structure to a selective etch process such that the exposed portions of the channel regions are recessed within the spacers.

10. The method of claim 9, wherein the parallel silicon germanium fins of the structure have widths between six and ten nanometers, and further wherein the selective etch process causes reduction of the widths and heights of the source/drain regions of the parallel silicon germanium fins by two nanometers or more.

11. The method of claim 10, further wherein the selective etch process causes a peripheral portion of each of the silicon germanium fins to be recessed within the spacers by two nanometers or more.

12. A FinFET structure comprising:
a substrate;
a plurality of rows of parallel silicon germanium fins on the substrate, each of the fins including a channel region and source/drain regions;
a plurality of parallel gate structures on the substrate and extending across the channel regions of the parallel silicon germanium fins;
a plurality of spacers on the parallel gate structures;
a dielectric layer on the substrate and between the parallel silicon germanium fins;
doped source/drain epitaxial structures on the source/drain regions of the parallel silicon germanium fins, and
doped source/drain extension regions between the channel regions and the source/drain regions of the parallel silicon germanium fins, the doped source/drain extension regions and the doped source/drain epitaxial structures containing the same dopant,
wherein the source/drain regions of the parallel silicon germanium fins have smaller height and width dimensions than the channel regions thereof, the channel regions include exposed surfaces within the spacers, and the doped source/drain epitaxial structures extend within the spacers and directly contact the exposed surfaces of the channel regions.

13. The FinFET structure of claim 12, wherein the source/drain regions have sidewalls including (110) surfaces, and wherein the doped source/drain epitaxial structures are faceted structures on the (110) surfaces.

14. The FinFET structure of claim 13, wherein the channel regions of the parallel silicon germanium fins of the structure have widths between six and ten nanometers and the source/drain regions of the parallel silicon germanium fins have widths at least two nanometers less than the widths of the channel regions.

15. The FinFET structure of claim 14, wherein the height of the channel regions of the parallel silicon germanium fins is at least two nanometers greater than the height of the source/drain regions thereof.

16. The FinFET structure of claim 16, wherein the exposed surfaces of the channel regions of the parallel silicon germanium fins include first and second vertically extending surfaces adjoining and extending substantially perpendicularly to the sidewalls of the source/drain regions.

17. The FinFET structure of claim 17, wherein the source/drain regions of the parallel silicon germanium fins include top surfaces and the exposed surfaces of the channel regions of the parallel silicon germanium fins include horizontally extending surfaces that extend between the first and second vertically extending surfaces and perpendicular to the top surfaces of the source/drain regions.

18. The FinFET structure of claim 18, wherein the parallel silicon germanium fins consist essentially of Si₁₋ₓGeₓ where x is 0.2 or greater.

19. The FinFET structure of claim 19, wherein the spacers have thicknesses between two and ten nanometers and the source/drain epitaxial structures extend between two and five nanometers within the spacers.
